(19) United States
(12) Patent Application Publication
(10) Pub. No.: US 2016/0079443 A1
(43) Pub. Date: Mar. 17, 2016

(54) JUNCTION BARRIER SCHOTTKY DIODE

(71) Applicant: RICHTEK TECHNOLOGY CORP, Hsinchu (TW)

(72) Inventors: Chung-Yu Hung, Hsinchu (TW); Ching-Yao Yang, Hsinchu (TW); Tzu-Cheng Kao, Hsinchu (TW); Tsung-Yi Huang, Hsinchu (TW); Wu-Te Weng, Hsinchu (TW)

(21) Appl. No.: 14/526,843

(22) Filed: Oct. 29, 2014

(30) Foreign Application Priority Data
Sep. 16, 2014 (TW) 10313866

(51) Int. Cl. H01L 29/872; H01L 27/02

(52) U.S. Cl. CPC H01L 29/872; H01L 27/0248

(57) ABSTRACT

A JBS diode includes a silicon substrate, a first P doped region, a metal layer, a second P doped region, and a first N doped region. The silicon substrate includes an upper surface. An NBL is provided in the bottom of the silicon substrate. An N well is provided between the upper surface and the NBL. The first P doped region is arranged in the N well, and extending downward from the upper surface. The metal layer covers the upper surface, and located on a side of the first P doped region. The second P doped region is arranged in the N well, extending downward from the upper surface, and located at the other side of the first P doped region. The first N doped region is arranged in the N well, extending downward from the upper surface, and located at the other side of the first P doped region.

### CROSS REFERENCE TO RELATED APPLICATIONS

This non-provisional application claims priority claim under 35 U.S.C. §119(a) on Patent Application No. 103121177 filed in Taiwan, R.O.C. on Jun. 19, 2014, the entire contents of which are hereby incorporated by reference herein.

### BACKGROUND

1. Technical Field

This disclosure relates to a junction barrier Schottky (JBS) diode, and in particular, to a JBS diode with a desirable electrostatic discharge effect.

2. Related Art

FIG. 1 is a structural sectional view of a JBS diode 100 in the art. The JBS diode 100 includes a silicon substrate 110, a field oxide 120, a field oxide 130, multiple P doped regions 140, a metal layer 150, and an N doped region 160.

The silicon substrate 110 has an upper surface 111. An N buried layer (NBL) 112 is provided in the bottom, opposite the upper surface 111, of the silicon substrate 110. An N well 113 is provided between the upper surface 111 of the silicon substrate 110 and the NBL 112. The field oxide 120 and the field oxide 130 are separately arranged in the N well 113, and extend downward from the upper surface 111. The multiple P doped regions 140 are located at a side of the field oxide 120 and separately arranged in the N well 113, and each P doped region extends downward from the upper surface 111.

The metal layer 150 covers the upper surface 111, and is located on the multiple P doped regions 140. The metal layer 150 is electrically led out to form a positive contact 170 of the JBS diode 100. The N doped region 160 is located between the field oxide 120 and the field oxide 130, and extends downward from the upper surface 111. The N doped region 160 is mainly used to lead out a current from the N well 113, and form a negative contact 180 of the JBS diode 100.

In FIG. 1, a Schottky diode component 101 indicated by dashed lines an equivalent illustration of the JBS diode 100. The metal layer 150 is led out to form the positive contact 170, and the N doped region 160 is led out to form the negative contact 180. A joint surface between the metal layer 150 and the N well 113 directly decides main characteristics, and a main current path occurs in the N well 113. In addition, as shown by the dashed lines in FIG. 1, a parasitic diode component 102 is further formed between the P doped regions 140 and the N well 113. The parasitic diode component 102 is connected in parallel to the equivalent Schottky diode component 101. However, because a forward bias voltage of the Schottky diode component 101 is smaller than that of the diode component 102, for normal forward bias use, characteristics of the Schottky diode component 101 still prevail.

However, the general conventional JBS diode 100 has a high electrostatic discharge capability, especially when static electricity occurs at two ends of the JBS diode 100 in a form of a negative voltage. A conventional solution is that a group of electrostatic discharge components are connected in parallel on the JBS diode 100 to enhance the electrostatic discharge capability of the JBS diode 100. However, the introduction of the electrostatic discharge components increases the apparatus size and cost.

### SUMMARY

To solve the foregoing problem, this disclosure mainly provides a JBS diode, and in particular, a JBS diode with a desirable electrostatic discharge effect.

This disclosure provides a JBS diode, including a silicon substrate, a first P doped region, a metal layer, a second P doped region, and a first N doped region. The silicon substrate has an upper surface; an NSL is provided in the bottom, opposite the upper surface, of the silicon substrate; and an N well is provided between the upper surface of the silicon substrate and the NBL, and extends downward from the upper surface. The first P doped region is arranged in the N well and extends downward from the upper surface. The metal layer covers the upper surface and is located on a side of the first P doped region. The second P doped region is arranged in the N well, extends downward from the upper surface, and is located at the other side of the first P doped region. The first N doped region is arranged in the N well, extends downward from the upper surface, and is located at the other side of the first P doped region.

In an embodiment of this disclosure, the JBS diode further includes multiple third P doped regions, arranged in the N well, extending downward from the upper surface, and located at a side of the first P doped region and under the metal layer.

In an embodiment of this disclosure, the JBS diode further includes multiple first field oxides, arranged in the N well, extending downward from the upper surface, and located at a side of the first P doped region and under the metal layer.

In an embodiment of this disclosure, the JBS diode further includes a second field oxide, arranged in the N well, extending downward from the upper surface, and located between the first P doped region and the first N doped region.

In an embodiment of this disclosure, the first N doped region is located between the second P doped region and the first P doped region.

In an embodiment of this disclosure, the second P doped region is located between the first N doped region and the first P doped region.

In an embodiment of this disclosure, the first N doped region is adjacent to the second P doped region.

In an embodiment of this disclosure, the JBS diode further includes a P lightly doped region located under the second P doped region.

In an embodiment of this disclosure, the JBS diode further includes a second N doped region, arranged in the N well, and extending downward from the upper surface, where the second P doped region is located between the first N doped region and the second N doped region.

In an embodiment of this disclosure, the first N doped region, the second P doped region, and the second N doped region are adjacent two by two.

In an embodiment of this disclosure, the JBS diode further includes a third P doped region, arranged in the N well, and extending downward from the upper surface, where the first N doped region is located between the second P doped region and the third P doped region.

In an embodiment of this disclosure, the second P doped region, the first N doped region, and the third P doped region are adjacent two by two.

The efficacy of this disclosure is that the JBS diode disclosed in this disclosure can enhance, by using a parasitic PNP bipolar junction transistor (BJT) component in the structure of the JBS diode, an electrostatic charge guiding capability of the JBS diode when the JBS diode is impacted by reverse static electricity, thereby enhancing a reverse electrostatic discharge capability of the JBS diode.

For features, implementations, and effects of the present creation, the optimal embodiments are described in detail with reference to the accompanying drawings in the following.

### BRIEF DESCRIPTION OF THE DRAWINGS

FIG. 1 is a structural sectional view of a JBS diode in the art;

FIG. 2 is a structural sectional view of a first embodiment of a JBS diode according to this disclosure;

FIG. 3 is a structural sectional view of a second embodiment of a JBS diode according to this disclosure;

FIG. 4 is a structural sectional view of a third embodiment of a JBS diode according to this disclosure:

FIG. 5 is a structural sectional view of a fourth embodiment of a JBS diode according to this disclosure; and

FIG. 6 is a current-voltage relationship view of a JBS diode of this disclosure and the prior art and a curve view of a reverse-biased leakage current.

### DETAILED DESCRIPTION

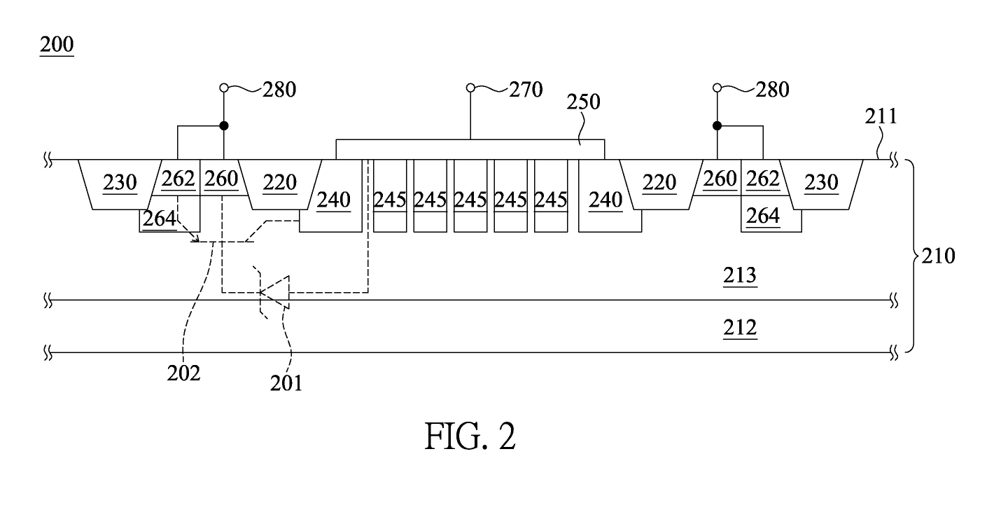

FIG. 2 is a structural sectional view of a first embodiment of a JBS diode 200 according to this disclosure. The JBS diode 200 in this disclosure is a component implemented by using a semiconductor process. The JBS diode 200 includes a silicon substrate 210, a first P doped region 240, a metal layer 250, a second P doped region 262, and a first N doped region 260.

The silicon substrate 210 has an upper surface 211. An NBL 212 is provided in the bottom, opposite the upper surface 211, of the silicon substrate 210. An N well 213 is provided between the upper surface 211 of the silicon substrate 210 and the NBL 212. The NBL 212 is used to reduce a leakage current between upper components, so that components are more densely arranged to reduce an overall area.

The first P doped region 240 is arranged in the N well 213 and extends downward from the upper surface 211. The metal layer 250 covers the upper surface 211 and is located on a side of the first P doped region 240. A joint surface between the metal layer 250 and the N well 213 forms a metal-semiconductor joint surface of the JBS diode 200, and directly decides main characteristics of the JBS diode 200. The metal layer 250 is also electrically led out to form a positive contact 270 of the JBS diode 200. The second P doped region 262 is arranged in the N well 213, extends downward from the upper surface 211, and is located at a side of the first P doped region 240. The first N doped region 260 is arranged in the N well 213, extends downward from the upper surface 211, and is located at the other side of the first P doped region 240.

In the embodiment shown in FIG. 2, the first N doped region 260 is located between the second P doped region 262 and the first P doped region 240. However, it should be noted that the structure of the JBS diode 200 disclosed in this disclosure is not limited thereto.

In FIG. 2, a Schottky diode component 201 indicated by dashed lines is an equivalent illustrated component of the JBS diode 200. Further, the metal layer 250 is led out to form the positive contact 270, and the N doped region 260 is led out to form a negative contact 280. A joint surface between the metal layer 250 and the N well 213 directly decides main characteristics, and a main current path occurs in the N well 213. In addition, a structure of the second P doped region 262, the N well 213, and the first P doped region 240 forms a parasitic PNP BJT component 202 as shown by dashed lines in FIG. 2. A potential of the N well 213 is decided by leading out of the first N doped region 260. An emitter and a base of the parasitic transistor component 202 are connected in parallel to the equivalent Schottky diode component 201. However, because a forward bias voltage of the Schottky diode component 201 is smaller than a forward bias voltage between the emitter and the base of the transistor component 202, for normal forward bias use, characteristics of the Schottky diode component 201 still prevail.

However, when the JBS diode 200 is impacted by reverse static electricity, a reverse-biased current is first formed between the positive contact and the negative contact of the JBS diode 200. The reverse-biased current mainly flows in from the negative contact 280, flows through the first N doped region 260, the N well 213, and the metal layer 250, and finally flows out from the positive contact 270. When the reverse-biased current increases to a certain value to produce a voltage drop in the N well 213 sufficiently large resulting in conduction between the emitter and the base of the transistor component 202, the transistor component 202 is turned on. Moreover, a high forward current capability is formed in a main path of the transistor, namely, between the second P doped region 262 and the first P doped region 240, thereby enhancing an electrostatic charge guiding capability. That is, the presence of the parasitic transistor component 202 strengthens a reverse electrostatic discharge capability of the JBS diode 200.

Further, the JBS diode 200 disclosed in this disclosure may further include multiple reverse-biased leakage current suppressing structures 245, arranged in the N well 213, extending downward from the upper surface 211, and located at a side of the first P doped region 240 and under the metal layer 250. The reverse-biased leakage current suppressing structures 245 may be a structure of multiple P doped regions (for example, defined as multiple third P doped regions) or multiple field oxides (for example, defined as multiple first field oxides). The structure of the field oxide also includes a shallow trench isolation (STI) structure in an advanced process (after a 0.35 micron process). Main current paths of the JBS diode 200 are formed in regions, between the reverse-biased leakage current suppressing structures 245 and between the reverse-biased leakage current suppressing structures 245 and the first P doped region 240, of the N well 213. The arrangement of the structure of the reverse-biased leakage current suppressing structures 245 can reduce the amount of leakage current between the positive contact and the negative contact during reverse bias of the JBS diode 200.

Further, as shown in FIG. 2, the structure of the JBS diode 200 may further include a second field oxide 220, arranged in the N well 213, extending downward from the upper surface 211, and located between the first P doped region 240 and the first N doped region 260. The second field oxide 220 is a structure that is usually formed during fabrication of the JBS diode 200 in combination with a semiconductor process, and therefore may serve as one of structural features of the JBS diode 200. However, it should be noted that the second field oxide 220 is not an essential structure. In addition, the JBS diode 200 may further include a third field oxide 230 that is located at the outermost layer of the structure of the JBS diode 200 for separation from other components.

As shown in FIG. 2, in yet another embodiment of this disclosure, the first N doped region 260 is adjacent to the second P doped region 262, which is a preferred implementation manner and enables the area of the JBS diode 200 to be small, so as to save hardware cost. However, the adjacency manner is not an essential arrangement manner, and the first N doped region 260 and the second P doped region 262 may be spaced by a specific distance, which does not affect main characteristics of the JBS diode 200 disclosed in this disclosure.

Further, as shown in FIG. 2, in yet another embodiment of this disclosure, a P lightly doped region 264 may further be included, which is located under the second P doped region 262. The P lightly doped region 264 has a P doping concentration lighter than that of the first P doped region 240; therefore, a beta (β) gain of the parasitic transistor component 202 is strengthened, that is, the parasitic transistor component 202 has a stronger current conduction effect; in this way, a reverse electrostatic discharge capability of the JBS diode 200 disclosed in this disclosure is also strengthened.

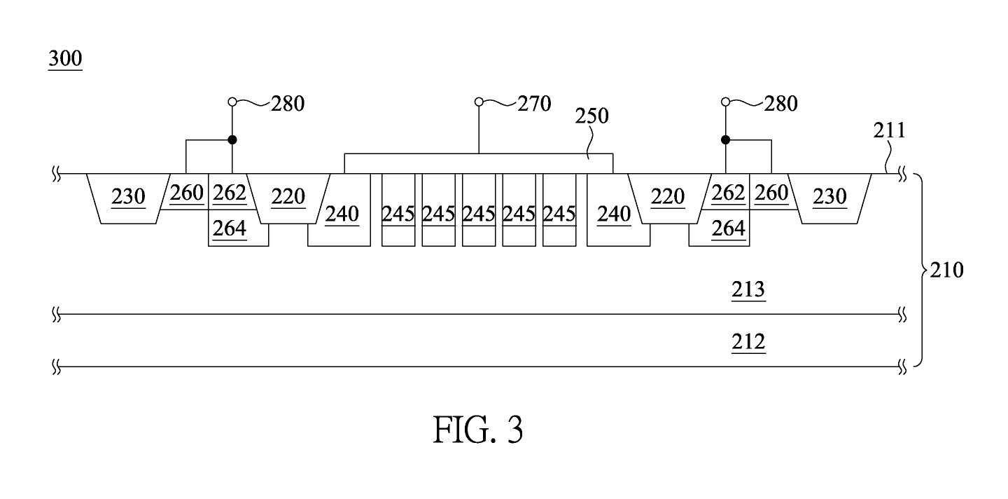

FIG. 3 is a structural sectional view of a second embodiment of a JBS diode 300 according to this disclosure. A difference between the JBS diode 300 in this disclosure and the JBS diode 200 in the first embodiment lies in that the first N doped region 260 of the JBS diode 200 in the first embodiment is located between the second P doped region 262 and the first P doped region 240, but the second P doped region 262 of the JBS diode 300 in the second embodiment is located between the first N doped region 260 and the first P doped region 240. In the structure formed by the JBS diode 300, the first N doped region 260 is far away from the first P doped region 240. In this way, when a reverse bias occurs on the JBS diode 300 and a reverse-biased current is formed, for a same current value, a larger voltage drop is caused in the N well 213, so that the parasitic transistor component (the component 202 shown in FIG. 2) of the JBS diode 300 is more easily turned on, thereby having a higher reverse electrostatic discharge capability.

In addition, as shown in FIG. 3, the first N doped region 260 of the JBS diode 300 in this disclosure is adjacent to the second P doped region 262, which is a desirable implementation manner, but does not constitute any limitation. Reference may be made to related description in the first embodiment, which is no longer elaborated herein. Moreover, in yet another embodiment of the JBS diode 300, the P lightly doped region 264 may be further included, which is located under the second P doped region 262.

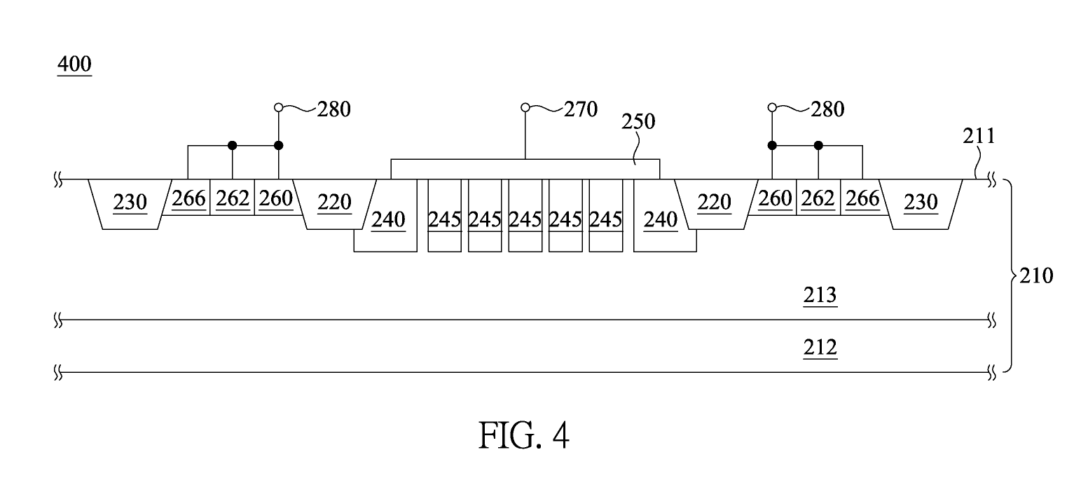

FIG. 4 is a structural sectional view of a third embodiment of a JBS diode 400 according to this disclosure. A difference from the JBS diode 200 in the first embodiment lies in that the JBS diode 400 further includes a second N doped region 266, arranged in the N well 213, and extending downward from the upper surface 211. The second P doped region 262 is located between the first N doped region 260 and the second N doped region 266. This is a variation in structure, and reference may be made to the description in the first embodiment for component effects; the variation in structure is no longer elaborated herein.

In addition, as shown in FIG. 4, in yet another embodiment of the JBS diode 400 disclosed in this disclosure, the first N doped region 260, the second P doped region 262, and the second N doped region 266 are arranged densely in a manner of being adjacent two by two, which is a desirable implementation manner, but does not constitute any limitation. Reference may be made to related description in the first embodiment, which is no longer elaborated herein.

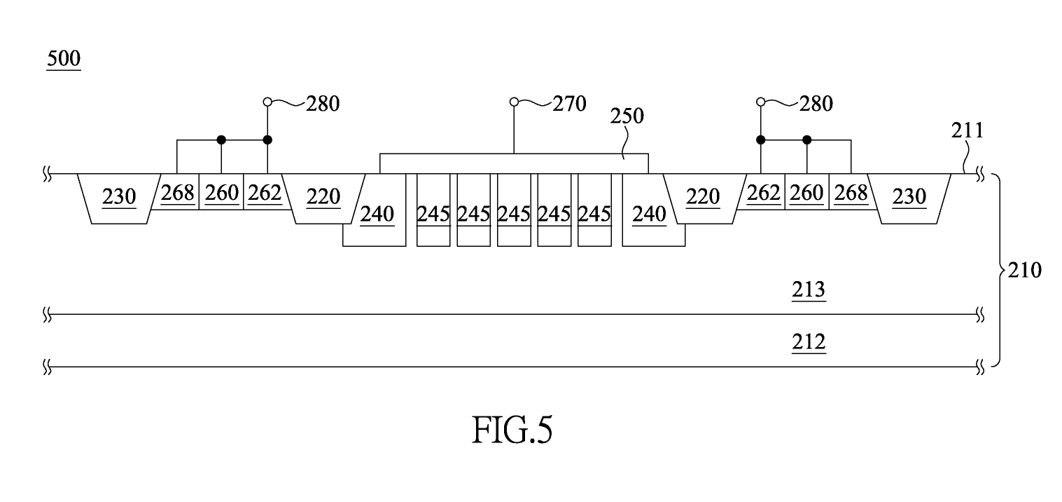

FIG. 5 is a structural sectional view of a fourth embodiment of a JBS diode 500 according to this disclosure. A difference from the JBS diode 200 in the first embodiment lies in that the JBS diode 500 further includes a third P doped region 268, arranged in the N well 213, and extending downward from the upper surface 211. The first N doped region 260 is located between the second P doped region 262 and the third P doped region 268. This is a variation in structure, and reference may be made to the description in the first embodiment for component effects; the variation in structure is no longer elaborated herein.

In addition, as shown in FIG. 5, in yet another embodiment of the JBS diode 500 in this disclosure, the second P doped region 262, the first N doped region 260, and the third P doped region 268 are arranged densely in a manner of being adjacent two by two, which is a desirable implementation manner, but does not constitute any limitation. Reference may be made to related description in the first embodiment, which is not described again herein.

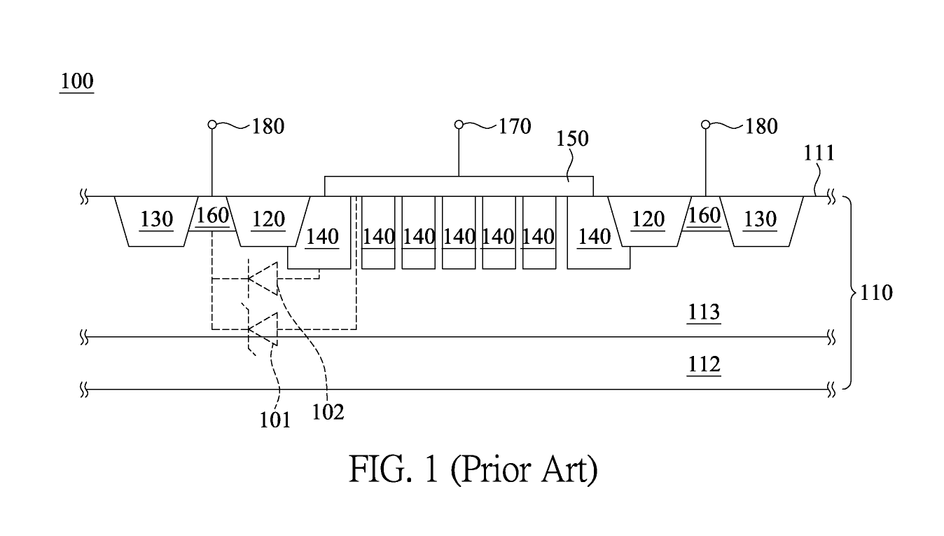

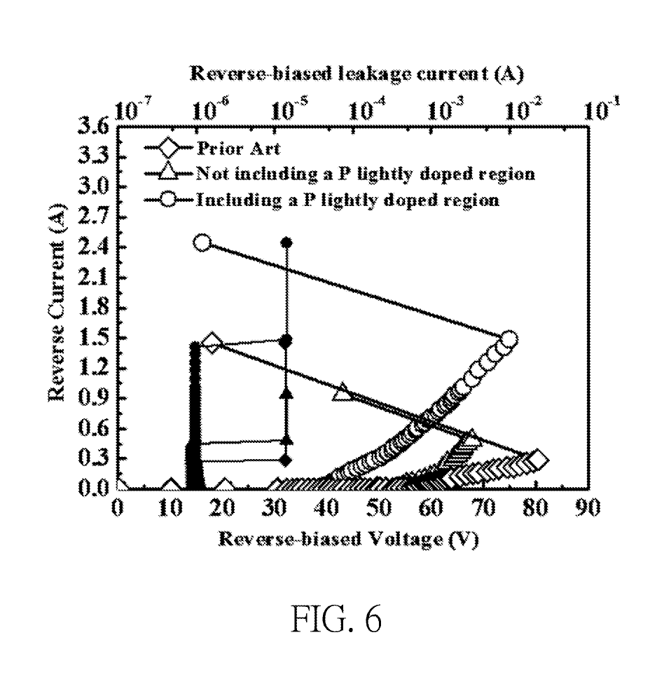

FIG. 6 is a current-voltage relationship view of a JBS diode of this disclosure and the prior art and a curve view of a reverse-biased leakage current. In the disclosure of this disclosure, the JBS diode 200 in the first embodiment is used as a measurement object, and two types of “not including the P lightly doped region 264” (square marks in FIG. 6) and “including the P lightly doped region 264” (triangle marks in FIG. 6) are further categorized. In the prior art, the JBS diode 100 disclosed in FIG. 1 is used as a measurement object (diamond marks in FIG. 6). Curves 610, 620, and 630 are relationship views between a reverse current and a reverse-biased voltage, where a horizontal axis shall correspond to a lower axis, namely, a “reverse-biased voltage”. In curves 630, 640, and 650, after each time a certain reverse-biased voltage is used to perform measurement, a reverse-biased voltage (for example, 5 volts) in a general application is further used to measure a reverse-biased leakage current, where a horizontal axis shall correspond to an upper axis, namely, a “reverse-biased leakage current”. It can be found in FIG. 6 that, for JBS diodes of three structures, before an excessively large reverse-biased voltage is provided to damage the JBS diodes, the order of magnitude of the differences among the reverse-biased leakage currents of the JBS diodes are not large and are about 1 microampere. Therefore, in a normal application, component characteristics of the JBS diodes should not be very different. Moreover, corresponding to a specific reverse-biased voltage, for example, 65 volts, it can be found that a conducted reverse current of the JBS diode in the prior art is the smallest, that is, the JBS diode has the lowest capability for guiding a reverse static voltage charge and the lowest electrostatic discharge capability; the structure of the JBS diode “not including the P lightly doped region 264” has a larger conducted reverse current; the structure of the JBS diode “including the P lightly doped region 264” has the largest conducted reverse current; this proves the foregoing description that “The P lightly doped region 264 has a P doping concentration lighter than that of the first P doped region 240; therefore, a beta (β) gain of the parasitic transistor component 202 is strengthened, that is, the parasitic transistor component 202 has a stronger current conduction effect; in this way, a reverse electrostatic discharge capability of the JBS diode 200 disclosed in this disclosure is also emphasized.

What is claimed is:

1. A junction barrier Schottky diode, comprising:
a silicon substrate, including an upper surface, wherein an N buried layer is provided in the bottom, opposite the upper surface, of the silicon substrate, and an N well is provided between the upper surface of the silicon substrate and the N buried layer;
a first P doped region, arranged in the N well, and extending downward from the upper surface;
a metal layer, covering the upper surface, and located on a side of the first P doped region;
a second P doped region, arranged in the N well, extending downward from the upper surface, and located at the other side of the first P doped region; and
a first N doped region, arranged in the N well, extending downward from the upper surface, and located at the other side of the first P doped region.

2. The junction barrier Schottky diode as claimed in claim 1, further comprising multiple third P doped regions, arranged in the N well, extending downward from the upper surface, and located at a side of the first P doped region and under the metal layer.

3. The junction barrier Schottky diode as claimed in claim 1, further comprising multiple first field oxides, arranged in the N well, extending downward from the upper surface, and located at a side of the first P doped region and under the metal layer.

4. The junction barrier Schottky diode as claimed in claim 1, further comprising a second field oxide, arranged in the N well, extending downward from the upper surface, and located between the first P doped region and the first N doped region.

5. The junction barrier Schottky diode as claimed in claim 1, wherein the first N doped region is located between the second P doped region and the first P doped region.

6. The junction barrier Schottky diode as claimed in claim 1, wherein the second P doped region is located between the first N doped region and the first P doped region.

7. The junction barrier Schottky diode as claimed in claim 1, wherein the first N doped region is adjacent to the second P doped region.

8. The junction barrier Schottky diode according to claim 1, further comprising a P lightly doped region located under the second P doped region.

9. The junction barrier Schottky diode as claimed in claim 5, further comprising a second N doped region, arranged in the N well, and extending downward from the upper surface, and the second P doped region is located between the first N doped region and the second N doped region.

10. The junction barrier Schottky diode as claimed in claim 7, wherein the first N doped region, the second P doped region, and the second N doped region are adjacent two by two.

11. The junction barrier Schottky diode as claimed in claim 6, further comprising a third P doped region, arranged in the N well, and extending downward from the upper surface, and the first N doped region is located between the second P doped region and the third P doped region.

12. The junction barrier Schottky diode as claimed in claim 11, wherein the second P doped region, the first N doped region, and the third P doped region are adjacent two by two.
